(19) United States
(12) Patent Application Publication
(10) Pub. No.: US 2026/0150509 A1
(43) Pub. Date: May 28, 2026

(54) Display Apparatus

(71) Applicant: LG Display Co., Ltd., Seoul (KR)

(72) Inventors: Heetae Lim, Paju-si (KR); Hoyoung Lee, Paju-si (KR); Heechul An, Paju-si (KR); Sungyub Lee, Paju-si (KR); Dongmin Yi, Paju-si (KR); Jiwan Kim, Paju-si (KR)

(21) Appl. No.: 19/314,196

(22) Filed: Aug. 29, 2025

(30) Foreign Application Priority Data
Nov. 28, 2024 (KR) 10-2024-0173297

(51) Int. Cl. H10K 59/122; H10K 50/19; H10K 59/35

(52) U.S. Cl. CPC H10K 59/122; H10K 59/353; H10K 50/19

(57) ABSTRACT

A display apparatus includes a substrate, a thin film transistor disposed on the substrate, a protective layer disposed on the thin film transistor, a first electrode disposed on the protective layer and electrically connected to the thin film transistor, a bank disposed across the first electrode and the protective layer and defining a light-emitting area exposing the first electrode and a trench exposing the protective layer, in which the bank defining the light-emitting area has a regularly-tapered shape, and the bank defining the trench has an inversely-tapered shape.

### CROSS REFERENCE TO RELATED APPLICATION

The present application claims priority to Republic of Korea Patent Application No. 10-2024-0173297, filed on Nov. 28, 2024, which is hereby incorporated by reference in its entirety.

### BACKGROUND

### Field of Technology

The present specification relates to a display apparatus.

### Description of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption than the LCD apparatus because it does not require a separate backlight. In addition, there is an advantage in that the OLED display apparatus can drive at a low voltage, have a fast response time, and especially have the inexpensive manufacturing cost.

### SUMMARY

The present specification is directed to providing a display apparatus in which an area with a different pixels per inch (PPI) can be formed without changing a fine metal mask (FMM).

The present specification is also directed to providing a display apparatus in which it is possible to suppress or prevent a solvent for removing an organic layer from overflowing to an adjacent other area.

The present specification is also directed to providing a display apparatus in which it is possible to increase a transmittance of a transmissive part.

Objects of the present specification are not limited to the above-described objects, and other technical objects may be inferred from the following embodiments.

According to one embodiment of the present specification, there is provided a display apparatus including a substrate, a thin film transistor disposed on the substrate, a protective layer disposed on the thin film transistor, a first electrode disposed on the protective layer and electrically connected to the thin film transistor, and a bank disposed across the first electrode and the protective layer and defining a light-emitting area exposing the first electrode and a trench expose the protective layer, wherein the bank defining the light-emitting area has a regularly-taped shape, and the bank defining the trench has an inversely-tapered shape.

According to another embodiment of the present specification, there is provided a display apparatus including a plurality of pixel areas in which a plurality of sub-pixels including a display area and a non-display area are disposed, a plurality of transmissive areas in which a trench is disposed, and a bank disposed between the plurality of pixel areas and defining the light-emitting area and the trench, wherein the plurality of pixel areas and the plurality of transmissive areas extend in a first direction, the pixel area and the transmissive area are alternately and repeatedly disposed in a second direction intersecting the first direction, and the transmissive area has a higher light transmittance than the pixel area.

According to the embodiments of the present specification, the area with different pixels per inch (PPI) can be formed without changing a fine metal mask (FMM).

According to the embodiments of the present specification, it is possible to suppress or prevent the solvent for removing an organic layer from overflowing to an adjacent other area.

According to the embodiments of the present specification, it is possible to increase the transmittance of the transmissive part.

According to the embodiments of the present specification, it is possible to suppress or prevent the solvent for removing an organic layer from overflowing to the adjacent other area, thereby optimizing the process of manufacturing the display apparatus and reducing production energy.

However, effects obtainable from the present specification are not limited to the above-described effects, and other effects that are not mentioned will be able to be clearly understood by those skilled in the art to which the present specification pertains based on the following description.

Detailed matters of other embodiments are included in the detailed description and accompanying drawings.

### BRIEF DESCRIPTION OF THE DRAWINGS

FIGS. 1 to 4 are schematic plan views of a display apparatus according to one embodiment.

FIG. 5 is a plan view of a first optical area of a display area according to one embodiment.

FIG. 6 is a cross-sectional view along line A-A′ in FIG. 5 according to one embodiment.

FIG. 7 is a specific cross-sectional view of a light-emitting part of FIG. 6 according to one embodiment.

FIG. 8 is a specific cross-sectional view of a light-emitting part according to a modified example according to one embodiment.

FIG. 9 is a cross-sectional view of a touch part according to FIG. 6 according to one embodiment.

FIG. 10 is a cross-sectional view along line B-B′ in FIG. 5 according to one embodiment.

FIG. 11 is an enlarged view of area Q1 in FIG. 10 according to one embodiment.

FIGS. 12 to 14 are views illustrating each process of a method of manufacturing a display apparatus according to one embodiment.

FIG. 15 is a cross-sectional view of a display apparatus according to another embodiment.

FIG. 16 is a cross-sectional view of a display apparatus according to still another embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

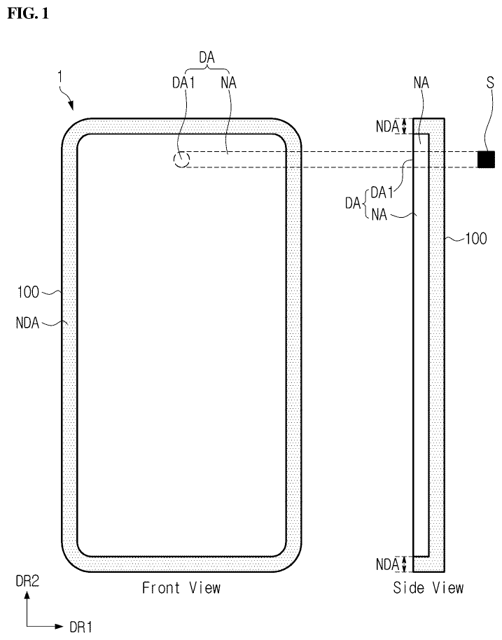

FIGS. 1 to 4 are schematic plan views of a display apparatus according to one embodiment.

Referring to FIGS. 1 to 4, a display apparatus 1 according to one embodiment of the present disclosure may include a display panel 100 for displaying an image and one or more optical electronic devices S, S1, and S2. The optical electronic devices S, S1, and S2 may include an electronic device (or a light-receiving device) for receiving light, such as a camera or a sensor.

The display panel 100 may include a display area DA and a non-display area NDA disposed around the display area DA. The display area DA is an area in which an image is displayed on the display panel 100. A plurality of sub-pixels forming a plurality of pixels and a circuit for driving the plurality of sub-pixels may be disposed in the display area DA.

The display area DA may include at least one of a normal area NA, a first optical area DA1, and a second optical area DA2, but is not limited thereto.

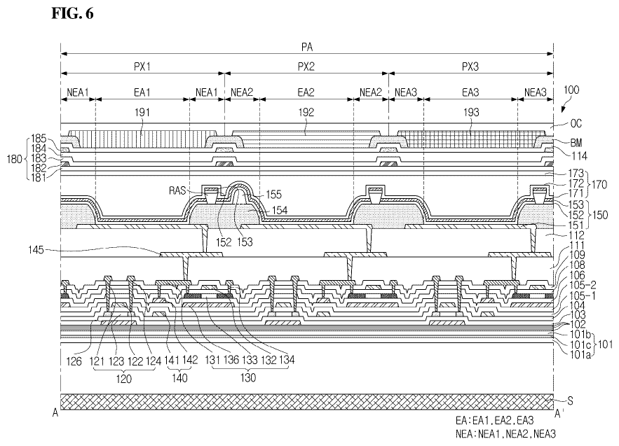

The normal area NA, the first optical area DA1, and the second optical area DA2 may be defined on a substrate 101 (see FIG. 6).

The flat surface shape of the display area DA may have a rectangular shape. However, the embodiments of the present specification are not limited thereto, and the flat surface shape of the display area DA may be square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2.

The non-display area NDA may surround the display area DA, but is not limited thereto. The non-display area NDA may be disposed at one side and the other side of the display area DA in the first direction DR1 and one side and the other side of the display area DA in the second direction DR2.

The non-display area NDA is an area in which a screen is not displayed and may define a bezel area.

In FIGS. 1 to 4, the one or more optical electronic devices S, S1, and S2 are electronic components located below (a side opposite to a viewing surface) the display panel 100.

Light may enter a front surface (a viewing surface) of the display panel 100, transmit the display panel 100, and may be transferred to the one or more optical electronic devices S, S1, and S2 located below (the side opposite to the viewing surface) the display panel 100.

The one or more optical electronic devices S, S1, and S2 may be devices for receiving light that has transmitted the display panel 100 and performing a predetermined function according to the received light.

For example, the optical electronic devices S, S1, and S2 may include one or more of a camera or a proximity sensor.

As described above, the optical electronic devices S, S1, and S2 are devices that require light reception, but may be located below the display panel 100. That is, the optical electronic devices S, S1, and S2 may be located at the side opposite to the viewing surface of the display panel 100. The optical electronic devices S, S1, and S2 are not exposed to the front of the display apparatus 1. Accordingly, when a user views the front surface of the display apparatus 1, the optical electronic devices S, S1, and S2 are not visible.

For example, the camera located below the display panel 100 is a front camera for capturing a forward image and may be viewed as a camera lens.

The optical electronic devices S, S1, and S2 may be disposed to overlap the display area DA of the display panel 100. That is, the optical electronic devices S, S1, and S2 may be located in the display area DA.

Referring to FIGS. 1 to 4, the display area DA may include the normal area NA and the one or more optical areas DA1 and DA2. Both the normal area NA and the one or more optical areas DA1 and DA2 may be areas in which the screen is displayed. The one or more optical areas DA1 and DA2 may be areas that overlap the one or more optical electronic devices S, S1, and S2.

According to the example of FIG. 1, the display area DA may include the normal area NA and a first optical area DA1. Here, at least a part of the first optical area DA1 may overlap the optical electronic device S. FIG. 1 illustrates the first optical area DA1 having a circular structure, but the shape of the first optical area DA1 according to one embodiment is not limited thereto.

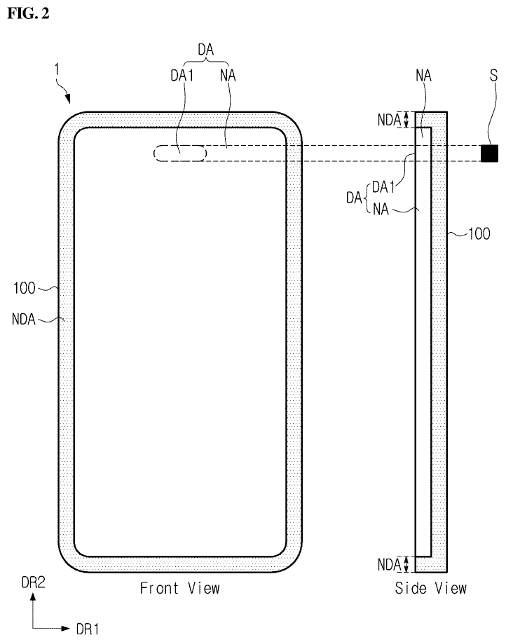

For example, as illustrated in FIG. 2, the shape of the first optical area DA1 may be an octagon and may also be formed in various polygonal shapes.

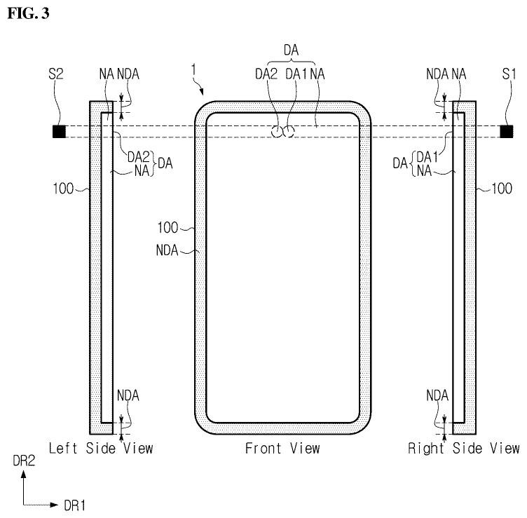

According to the example of FIG. 3, the display area DA may include the normal area NA, the first optical area DA1, and a second optical area DA2. In the example of FIG. 3, the normal area NA may be present between the first optical area DA1 and the second optical area DA2. Here, at least a part of the first optical area DA1 may overlap a first optical electronic device S1, and at least a part of the second optical area DA2 may overlap a second optical electronic device S2.

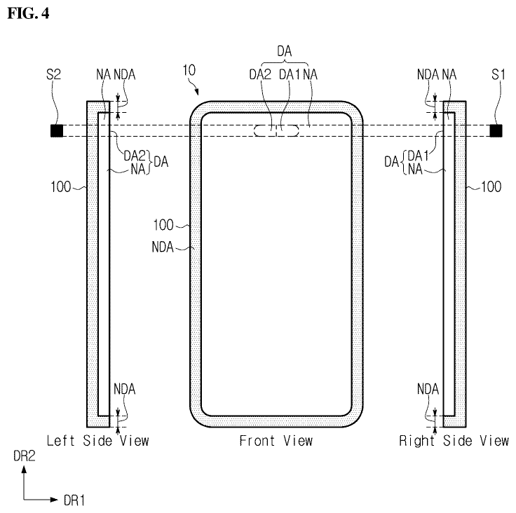

According to the example of FIG. 4, the display area DA may include the normal area NA, the first optical area DA1, and the second optical area DA2. In the example of FIG. 4, the normal area NA is not present between the first optical area DA1 and the second optical area DA2. That is, the first optical area DA1 may come into contact with the second optical area D2. Here, at least a part of the first optical area DA1 may overlap the first optical electronic device S1, and at least a part of the second optical area DA2 may overlap the second optical electronic device S2.

Both an image display structure and a light-transmitting structure need to be formed in the one or more optical areas DA1 and DA2. That is, since the one or more optical areas DA1 and DA2 are parts of the display area DA, sub-pixels for image display need to be disposed in the one or more optical areas DA1 and DA2. A light-transmitting structure for transmitting light to the one or more optical electronic devices S, S1, and S2 needs to be formed in the one or more optical areas DA1 and DA2.

The one or more optical electronic devices S, S1, and S2 are devices that require light reception, but are located behind (below, the side opposite to the viewing surface) the display panel 100 to receive light that has transmitted the display panel 100.

The one or more optical electronic devices S, S1, and S2 are not exposed to the front surface (the viewing surface) of the display panel 100. Accordingly, when a user views the front surface of the display apparatus 1, the optical electronic devices S, S1, and S2 are not visible to the user.

For example, the first optical electronic device S and S1 may be a camera, and the second optical electronic device S2 may be a detection sensor, such as a proximity sensor, an illuminance sensor, etc. For example, the detection sensor may be an infrared sensor for detecting infrared rays.

Conversely, the first optical electronic device S1 may be a detection sensor, and the second optical electronic device S2 may be a camera.

Hereinafter, for convenience of description, an example in which the first optical electronic device S and S1 is a camera and the second optical electronic device S2 is a detection sensor will be described. Here, the camera may be a camera lens or an image sensor.

When the first optical electronic device S and S1 is a camera, the camera is located behind (below) the display panel 100, but may be a front camera for capturing a forward image of the display panel 100. Accordingly, the user may capture an image through a camera that is not visible on the viewing surface while looking at the viewing surface of the display panel 100.

The normal area NA and the one or more optical areas DA1 and DA2 that are included in the display area DA are areas in which an image may be displayed, but the normal area NA is an area in which a light-transmitting structure does not need to be formed, and the one or more optical areas DA1 and DA2 are areas in which the light-transmitting structure needs to be formed.

Accordingly, the one or more optical areas DA1 and DA2 need to have a transmittance of a predetermined level or more, and the normal area NA may not have the light-transmitting property or may have a low transmittance less than the predetermined level.

For example, the one or more optical areas DA1 and DA2 may differ from the normal area NA in terms of a resolution, a sub-pixel arrangement structure, the number of sub-pixels per unit area, an electrode structure, a line structure, an electrode arrangement structure, a line arrangement structure, etc.

For example, the number of sub-pixels per unit area in the one or more optical areas DA1 and DA2 may be less than the number of sub-pixels per unit area in the normal area NA. That is, resolutions of the one or more optical areas DA1 and DA2 may be lower than a resolution of the normal area NA. In this case, the number of sub-pixels per unit area is a unit for measuring a resolution and may be referred to as pixels per inch (PPI) that refers to the number of pixels in 1 inch.

For example, the number of sub-pixels per unit area in the first optical area DA1 may be less than the number of sub-pixels per unit area in the normal area NA. The number of sub-pixels per unit area in the second optical area DA2 may be more than or equal to the number of sub-pixels per unit area in the first optical area DA1.

The first optical area DA1 may have various shapes, such as a circle, an ellipse, a square, a hexagon, an octagon, etc. The second optical area DA2 may have various shapes, such as a circle, an ellipse, a square, a hexagon, an octagon, etc. The first optical area DA1 and the second optical area DA2 may have the same shape or different shapes.

Referring to FIG. 3, when the first optical area DA1 comes into contact with the second optical area DA2, the entire optical area including the first optical area DA1 and the second optical area DA2 may also have various shapes, such as a circle, an ellipse, a square, a hexagon, an octagon, etc.

Hereinafter, for convenience of description, an example in which each of the first optical area DA1 and the second optical area DA2 is circular will be described.

In the display apparatus 1 according to one embodiment, when the first optical electronic device S and S1 that are not exposed to the outside and are hidden below the display panel 100 is an infrared sensor (or a near-infrared sensor), the display apparatus 1 according to one embodiment may be referred to as a display to which a UDIR technology is applied.

Accordingly, in the case of the display apparatus 1 according to one embodiment, since a notch or camera hole for camera exposure does not need to be formed in the display panel 100, an area of the display area DA is not reduced.

Accordingly, since the notch or camera hole for camera exposure does not need to be formed in the display panel 100, the size of the bezel area can be reduced, and since design restrictions are eliminated, the degree of freedom related to a design can be increased.

In a display apparatus 1 according to one embodiment, even though the one or more optical electronic devices S, S1, and S2 are located to be hidden behind the display panel 100, the one or more optical electronic devices S, S1, and S2 need to normally receive light and perform a predetermined function normally.

In addition, in the display apparatus 1 according to one embodiment, even though the one or more optical electronic devices S, S1, and S2 are located to be hidden behind the display panel 100 and overlap the display area DA, a normal image needs to be displayed in the one or more optical areas DA1 and DA2 overlapping the one or more optical electronic devices S, S1, and S2 in the display area DA.

Accordingly, the display apparatus 1 according to one embodiment of the present disclosure may have a structure capable of increasing the transmittances of the first optical area DA1 and the second optical area DA2 that overlap the optical electronic devices S, S1, and S2.

Hereinafter, the embodiment of FIG. 1 among the embodiments of FIGS. 1 to 4 will be mainly described, but the description of the normal area NA of FIG. 1 may be applied to the normal area NA of FIGS. 2 to 4 in the substantially the same manner, and the description of the first optical area DA1 of FIG. 1 may also be applied to the optical areas DA1 and DA2 of FIGS. 2 to 4 in the substantially the same manner.

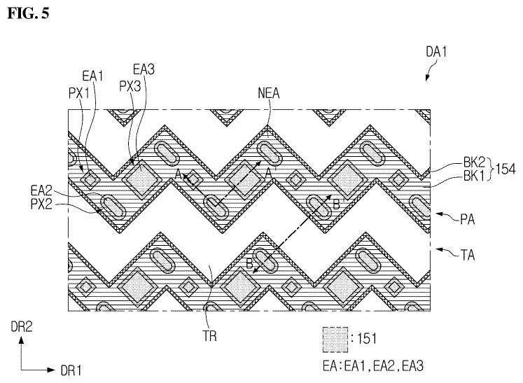

FIG. 5 is a plan view of a first optical area of a display area according to one embodiment. FIG. 6 is a cross-sectional view along line A-A′ in FIG. 5 according to one embodiment.

FIG. 5 illustrates an arrangement of sub-pixels PX1, PX2, and PX3 of the first optical area DA1 of the display area DA according to one embodiment. FIG. 6 illustrates the cross-sectional structure of each sub-pixel PX1, PX2, or PX3 in the pixel area PA.

Hereinafter, the description of the first optical area DA1 may be applied to the second optical area DA2 (see FIG. 2) in the substantially the same manner.

Referring to FIGS. 1, 5, and 6, the optical electronic device S may be disposed below the display panel 100. The optical electronic device S may be disposed to overlap the first optical area DA1 of the display panel 100. The first optical area DA1 may have a lower PPI than the normal area NA. For example, densities of the sub-pixels PX1, PX2, and PX3 in the first optical area DA1 may be smaller than densities of the sub-pixels PX1, PX2, and PX3 in the normal area NA.

The first optical area DA1 may include a pixel area PA in which the plurality of sub-pixels PX1, PX2, and PX3 are disposed, and a transmissive area TA disposed around the pixel area PA. The pixel area PA and the transmissive area TA may be defined on the substrate 101.

The pixel area PA and the transmissive area TA may have different light transmittances. The light transmittance of the transmissive area TA may be higher than the light transmittance of the pixel area PA.

The transmissive area TA is not disposed in the normal area NA, and the normal area NA may be formed of only the pixel area PA. Accordingly, the normal area NA may have a higher PPI than the first optical area DA1.

The plurality of sub-pixels PX1, PX2, and PX3 may be disposed in the first optical area DA1. The plurality of sub-pixels PX1, PX2, and PX3 may include a first sub-pixel PX1, a second sub-pixel PX2, and a third sub-pixel PX3.

For example, the plurality of sub-pixels may include a red sub-pixel (Red SP) (or the first sub-pixel PX1) that emits red light, a green sub-pixel (Green SP) (or the second sub-pixel PX2) that emits green light, and a blue sub-pixel (Blue SP) (or the third sub-pixel PX3) that emits blue light. FIG. 5 illustrates the flat surface shapes of the plurality of sub-pixels PX1, PX2, and PX3 are a square or an oval, but the embodiments of the present specification are not limited thereto, and the flat surface shapes of the plurality of sub-pixels PX1, PX2, and PX3 may be circular.

Accordingly, the pixel area PA may include a light-emitting area EA. The light-emitting area EA may include a plurality of light-emitting areas EA1, EA2, and EA3. The light-emitting areas EA1, EA2, and EA3 may be disposed in the sub-pixels PX1, PX2, and PX3, respectively. That is, the first sub-pixel PX1 may include a first light-emitting area EA1, the second sub-pixel PX2 may include a second light-emitting area EA2, and the third sub-pixel PX3 may include a third light-emitting area EA3.

The pixel area PA may further include non-light-emitting area NEA (NEA1, NEA2, and NEA3) disposed around the light-emitting area EA. A bank 154 may be disposed in the non-light-emitting area NEA.

The first sub-pixel PX1 may include a first light-emitting area NEA1, the second sub-pixel PX2 may include a second light-emitting area NEA2, and the third sub-pixel PX3 may include a third light-emitting area NEA3. The first non-light-emitting area NEA1 may be disposed around the first light-emitting area EA1, the second non-light-emitting area NEA2 may be disposed around the second light-emitting area EA2, and the third non-light-emitting area NEA3 may be disposed around the third light-emitting area EA3.

Each non-light-emitting area NEA1, NEA2, or NEA3 may correspond to boundaries between adjacent sub-pixels PX1, PX2, and PX3.

A pixel of the display panel 100 may include the plurality of sub-pixels PX1, PX2, and PX3. The first sub-pixel PX1 may be a red sub-pixel, the second sub-pixel PX2 may be a green sub-pixel, and the third sub pixel PX3 may be a blue sub-pixel, but the embodiments of the present specification are not limited thereto. In some embodiments, the pixel further includes a fourth sub-pixel, and the fourth sub-pixel may be a white sub-pixel, but the embodiments of the present specification are not limited thereto. In some embodiments, the pixel may include one red sub-pixel, two green sub-pixels, and one blue sub-pixel, but the embodiments of the present specification are not limited thereto. For example, the plurality of sub-pixels PX1, PX2, and PX3 may be arranged in a stripe manner in the first direction DR1, but are not limited thereto, and may be arranged in a pentile manner.

The pixel area PA may be provided as a plurality of pixel areas. Each pixel area PA may extend in the first direction DR1 and extend in the first direction DR1 in a zig-zag shape, but is not limited thereto. The plurality of sub-pixels PX1, PX2, and PX3 may be disposed alternately and repeatedly in each pixel area PA. Each of the plurality of pixel areas PA may be disposed repeatedly in the second direction DR2.

The transmissive area TA may be disposed between adjacent pixel areas PA in the second direction DR2. The sub-pixels PX1, PX2, and PX3 may not be disposed in the transmissive area TA.

The transmissive area TA may be provided as a plurality of transmissive areas. Each transmissive area TA may extend in the first direction DR1 and extend in the first direction DR1 in a zig-zag shape, but is not limited thereto. Each of the plurality of transmissive areas TA may be disposed repeatedly in the second direction DR2.

Each of the plurality of transmissive areas TA and each of the plurality of pixel areas PA may be disposed across the first optical area DA1 in the first direction DR1, but is not limited thereto.

The transmissive area TA may be an area capable of light transmission in which light entering from the outside of the display panel 100 may pass through the display panel 100 and may be emitted to the outside of the display panel 100. Through the transmissive area TA, external light may pass through the display panel 100 and reach the optical electronic device S.

The transmissive area TA may not overlap the light-emitting area EA. In addition, a light-shielding layer may be formed in the light-emitting area EA, but the light-shielding layer may not be formed in the transmissive area TA. A metal layer, such as transistors 120 and 130 that drives the light-emitting part and a storage capacitor 140, and lines connected thereto may not be disposed in the transmissive area TA. However, the embodiments of the present specification are not limited thereto, and the metal layers and some lines may be disposed in some areas of the transmissive area TA.

A trench TR defined by the bank 154 may be disposed in the transmissive area TA. The trench TR may be formed by recessing the bank 154 in a thickness direction.

The flat surface shape of the trench TR may correspond to the flat surface shape of the transmissive area TA, but is not limited thereto.

Hereinafter, the cross-sectional structure of the pixel area PA will be described.

The display panel 100 may include the substrate 101, a first thin film transistor 120, a second thin film transistor 130, a storage capacitor 140, a light-emitting part 150, an encapsulation part 170, a touch part 180, a filter insulating layer 114, a black matrix BM, color filters 191, 192, and 193, and a planarization layer OC.

The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present specification are not limited thereto.

The buffer layer 102 may be disposed on the substrate 101. The buffer layer 102 can minimize, reduce, or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present specification are not limited thereto.

A first light-shielding layer 126 may be disposed on the buffer layer 102. The first light-shielding layer 126 can prevent or at least reduce light from transmitting a first semiconductor layer 123 of the first thin film transistor 120. For example, the first semiconductor layer 123 may be disposed to overlap the first light-shielding layer 126. The first light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

The first insulating layer 103 may be disposed on the buffer layer 102 and the first light-shielding layer 126. The first insulating layer 103 can prevent or at least reduce a likelihood of a short circuit between a component of the first thin film transistor 120 and the first light-shielding layer 126. The first insulating layer 103 may be formed of the same material as the buffer layer 102, but the embodiments of the present specification are not limited thereto. For example, the first insulating layer 103 may be formed of an inorganic insulation material, such as silicon nitride (SiNₓ) or silicon oxide (SiOₓ), but the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

A second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or compounds thereof, but the embodiments of the present specification are not limited thereto. The first gate electrode 122 may be disposed along with a gate line.

The third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present specification are not limited thereto. For example, the 3-1 insulating layer 105-1 may include silicon oxide (SiOₓ), and the 3-2 insulating layer 105-2 may include silicon nitride (SiNₓ), but the embodiments of the present specification are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the present specification are not limited thereto.

The storage capacitor 140 may be disposed to be spaced apart from the first thin film transistor 120. The storage capacitor 140 may include a first storage electrode 141 and a second storage electrode 142.

The first storage electrode 141 may be formed of the same material as the first gate electrode 122 and disposed on the same layer as the first gate electrode 122, but the embodiments of the present specification are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

The second thin film transistor 130 may be disposed to be spaced apart from the first thin film transistor 120 and the storage capacitor 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 can prevent or at least reduce light from traveling to the second semiconductor layer 133 similar to the first light-shielding layer 126, thereby extending the life of the second thin film transistor 130. For example, the second semiconductor layer 133 may be disposed to overlap the second light-shielding layer 136.

The fourth insulating layer 106 may be disposed on the second light-shielding layer 136. The fourth insulating layer 106 may be formed of the same material as the first insulating layer 103, the second insulating layer 104, or the third insulating layers 105-1 and 105-2, but the embodiments of the present specification are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto.

The fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present specification are not limited thereto.

The second gate electrode 132 may be disposed on the fifth insulating layer 108. The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto.

The sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present specification are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but the embodiments of the present specification are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present specification are not limited thereto.

The first protective layer 111 may be disposed on the first source electrode 121, the first drain electrode 124, the second source electrode 131, and the second drain electrode 134.

The first protective layer 111 may planarize upper portions of the first thin film transistor 120 and the second thin film transistor 130 and protect the first thin film transistor 120 and the second thin film transistor 130. The first protective layer 111 may be formed of an organic material. For example, the first protective layer 111 may be formed of an organic material containing an acrylic resin, an epoxy resin, a phenolic resin, a polyamide resin, or a polyimide resin, but the embodiments of the present specification are not limited thereto.

The second protective layer 112 may be disposed on the first protective layer 111. The second protective layer 112 may be formed of the same material as the first protective layer 111, but the embodiments of the present specification are not limited thereto.

In some embodiments, a third protective layer may be further disposed on an upper surface of the second protective layer 112, but the embodiments of the present specification are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the present specification are not limited thereto.

The connection electrode 145 may be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The light-emitting part 150 may be disposed on the second protective layer 112. The light-emitting part 150 may include a first electrode 151, an organic layer 152, and a second electrode 153. The embodiments of the present specification are not limited thereto, but the first electrode 151 may serve as an anode, and the second electrode 153 may serve as a cathode.

The first electrode 151 may be disposed on the second protective layer 112. The first electrode 151 may be electrically connected to the connection electrode 145 through a contact hole formed in the second protective layer 112 and electrically connected to the first thin film transistor 120.

The first electrode 151 may be a reflective electrode that reflects light, but the embodiments of the present specification are not limited thereto. The first electrode 151 may include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present specification are not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer.

For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto.

The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto.

For example, the organic layer 152 of the display panel 100 according to one embodiment of the present specification may include an organic light-emitting layer. The organic layer 152 may include a red light-emitting layer, a green light-emitting layer, and a blue light-emitting layer. The organic layer 152 may be a white light-emitting layer, but the embodiments of the present specification are not limited thereto. Hereinafter, a specific structure of the organic layer 152 according to one embodiment will be described.

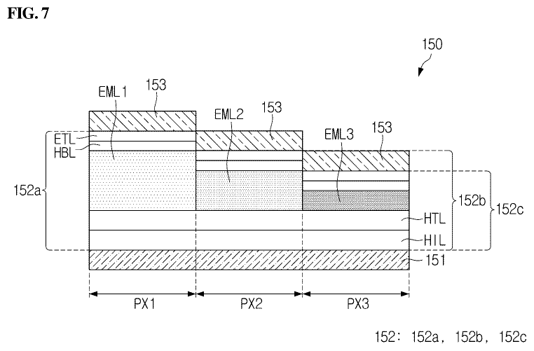

FIG. 7 is a specific cross-sectional view of a light-emitting part of FIG. 6 according to one embodiment.

Referring to FIG. 7, the light-emitting part 150 may be disposed across the first sub-pixel PX1, the second sub-pixel PX2, and the third sub-pixel PX3.

A thickness of the light-emitting part 150 in each sub-pixel PX1, PX2, or PX3 may be different, but the embodiments of the present specification are not limited thereto, and the thickness of the light-emitting part 150 in each sub-pixel PX1, PX2, or PX3 may be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels PX1, PX2, and PX3. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present specification are not limited thereto.

A hole injecting layer HIL may be disposed on the first electrode 151. The hole injecting layer HIL may be located between the first electrode 151 and the light-emitting layers EML1, EML2, and EML3. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be formed integrally across the sub-pixels PX1, PX2, and PX3. The hole transporting layer HTL may be formed of one or more selected from the group consisting of arylamine-based materials, such as NPB (N, N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″ Tris(N-3-methylphenyl-N-phenyl-amino)-triphenylamine), but the embodiments of the present specification are not limited thereto.

The light-emitting layers EML1, EML2, and EML3 may be disposed on the hole transporting layer HTL. The first light-emitting layer EML1 may be disposed in the first sub-pixel PX1, the second light-emitting layer EML2 may be disposed in the second sub-pixel PX2, and the third light-emitting layer EML3 may be disposed in the third sub-pixel PX3.

A thicknesses of each light-emitting layer EML1, EML2, or EML3 may be different. For example, the first light-emitting layer EML1 may be formed in a thickness of 600 to 800 angstroms (10⁻¹⁰ meters), the second light-emitting layer EML2 may be formed in a thickness of 300 to 500 angstroms (10⁻¹⁰ meters), and the third light-emitting layer EML3 may be formed in a thickness of 100 to 300 angstroms (10⁻¹⁰ meters), but the embodiments of the present specification are not limited thereto.

Each of the first light-emitting layer EML1, the second light-emitting layer EML2, and the third light-emitting layer EML3 may include a material that may emit light in the visible light range by receiving and combining holes and electrons.

A hole blocking layer HBL may be disposed on each light-emitting layer EML1, EML2, or EML3. The hole blocking layer HBL may be disposed integrally across the sub-pixels PX1, PX2, and PX3.

An electron transporting layer ETL may be disposed on the electron blocking layer HBL. The electron transporting layer ETL may be disposed integrally across the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the electron transporting layer ETL.

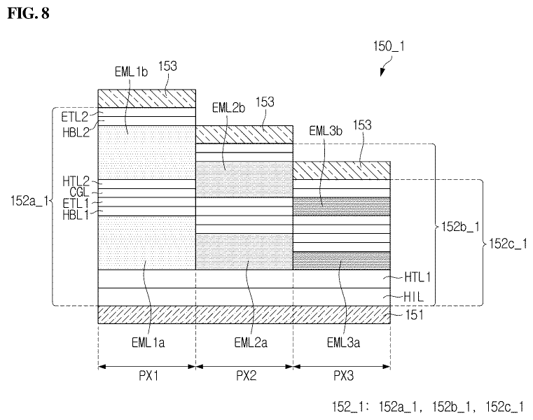

FIG. 8 is a specific cross-sectional view of a light-emitting part according to a modified example.

Referring to FIGS. 7 and 8, an organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 may be physically separated, but the lower layers and upper layers of the light-emitting layers may be formed integrally across the sub-pixels PX1, PX2, and PX3. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present specification are not limited thereto. In addition, the light-emitting layers of each organic layer 152a_1, 152b_1, or 152c_1 may be provided as two or more light-emitting layers.

A hole injecting layer HIL may be disposed on the first electrode 151. The hole injecting layer HIL may be located between the first electrode 151 and the light-emitting layers EML1a, EML2a, and EML3a. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be formed integrally across the sub-pixels PX1, PX2, and PX3. The first hole transporting layer HTL1 may be formed of one or more selected from the group consisting of arylamine-based materials, such as NPB (N, N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″-Tris(N-3-methylphenyl-N-phenyl-amino)-triphenylamine), but the embodiments of the present specification are not limited thereto.

The light-emitting layers EML1a, EML2a, and EML3a may be disposed on the first hole transporting layer HTL1. A 1-1 light-emitting layer EML1a may be disposed in the first sub-pixel PX1, a 2-1 light-emitting layer EML2a may be disposed in the second sub-pixel PX2, and a 3-1 light-emitting layer EML3a may be disposed in the third sub-pixel PX3. Each of the light-emitting layers EML1a, EML2a, and EML3a may be the same as each of the light-emitting layers EML1, EML2, and EML3 of FIG. 7.

A thicknesses of each light-emitting layer EML1a, EML2a, or EML3a may be different. For example, the first light-emitting layer EML1a may be formed in a thickness of 600 to 800 angstroms (10⁻¹⁰ meters), the second light-emitting layer EML2a may be formed in a thickness of 300 to 500 angstroms (10⁻¹⁰ meters), and the third light-emitting layer EML3a may be formed in a thickness of 100 to 300 angstroms (10⁻¹⁰ meters), but the embodiments of the present specification are not limited thereto.

A first hole blocking layer HBL1 may be disposed on each light-emitting layer EML1a, EML2a, or EML3a. The first hole blocking layer HBL1 may be formed integrally across the sub-pixels PX1, PX2, and PX3.

A first electron transporting layer ETL1 may be disposed on the first hole blocking layer HBL1. The first electron transporting layer ETL1 may be formed integrally across the sub-pixels PX1, PX2, and PX3. The first electron transporting layer ETL1 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

A common charge layer CGL may be disposed on the first electron transporting layer ETL1. The common charge layer CGL may be disposed between the first electron transporting layer ETL1 and the second hole transporting layer HTL2. The common charge layer CGL may include a conductive material, but the embodiments of the present disclosure are not limited thereto.

A second hole transporting layer HTL2 may be disposed on the common charge layer CGL. The second hole transporting layer HTL2 may be disposed between the hole blocking layer HBL and the light-emitting layers EML1b, EML2b, and EML3b. The second hole transporting layer HTL2 may be formed integrally across the sub-pixels PX1, PX2, and PX3. A material of the second hole transporting layer HTL2 may be the same as a material of the first hole transporting layer HTL1, but the embodiments of the present specification are not limited thereto.

The light-emitting layers EML1b, EML2b, and EML3b may be disposed on the second hole transporting layer HTL2. A 1-2 light-emitting layer EML1b may be disposed in the first sub-pixel PX1, a 2-2 light-emitting layer EML2b may be disposed in the second sub-pixel PX2, and a 3-2 light-emitting layer EML3b may be disposed in the third sub-pixel PX3. Each of the light-emitting layers EML1b, EML2b, and EML3b may be the same as each of the light-emitting layers EML1a, EML2a, and EML3a.

A thicknesses of each light-emitting layer EML1b, EML2b, or EML3b may be different. For example, the 1-2 light-emitting layer EML1b may be formed in a thickness of 600 to 800 angstroms (10⁻¹⁰ meters), the 2-2 light-emitting layer EML2b may be formed in a thickness of 300 to 500 angstroms (10⁻¹⁰ meters), and the 3-2 light-emitting layer EML3b may be formed in a thickness of 100 to 300 angstroms (10⁻¹⁰ meters), but the embodiments of the present specification are not limited thereto.

A second hole blocking layer HBL2 may be disposed on each light-emitting layer EML1b, EML2b, or EML3b. The second hole blocking layer HBL2 may be formed integrally across the sub-pixels PX1, PX2, and PX3.

A second electron transporting layer ETL2 may be disposed on the second hole blocking layer HBL2. The second electron transporting layer ETL2 may be formed integrally across the sub-pixels PX1, PX2, and PX3. The second electron transporting layer ETL2 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the second electron transporting layer ETL2.

Referring back to FIG. 6, the second electrode 153 may be disposed on the organic layer 152. The second electrode 153 may be a transparent electrode that transmits light, but the embodiments of the present specification are not limited thereto. For example, the second electrode 153 may include a transparent conductive material, such as indium tin oxide (ITO) or indium zinc oxide (IZO), or a metal that transmits visible light, but the embodiments of the present specification are not limited thereto.

The bank 154 may be disposed to expose the first electrode 151. The bank 154 may be disposed to define the light-emitting area EA (EA1, EA2, and EA3 of the sub-pixels PX1, PX2, and PX3 and cover an edge portion (or a periphery) of the first electrode 151.

The non-light-emitting area NEA may be disposed around the light-emitting area EA. The bank 154 may be disposed in the non-light-emitting area NEA.

The light-emitting area EA may include the first light-emitting area EA1, the second light-emitting area EA2, and the third light-emitting area EA3 that are disposed in the sub-pixels PX1, PX2, and PX3, respectively. The non-light-emitting area NEA may include the first non-light-emitting area NEA1, a second non-light-emitting area (NEA2), and a third non-light-emitting area NEA3 that are disposed around the light-emitting areas EA1, EA2, and EA3, respectively.

That is, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, each non-light-emitting area NEA1, NEA2, or NEA3 may correspond to a boundary between adjacent sub-pixels PX1, PX2, and PX3.

The bank 154 may include a hydrophilic organic material and/or a hydrophobic organic material.

For example, the bank 154 may be formed of an organic material, such as a benzocyclobutene resin, a polyimide resin, an acrylic resin, a photosensitive polymer, etc. However, the embodiments of the present specification are not limited thereto, and the bank 154 may further include a black-based material. For example, the bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be an opaque bank. When the bank 154 is formed of a material containing black pigment or black dye, it is possible to shield external light or light reflected from the outside, thereby further increasing the luminance of the display apparatus.

A barrier RAS may be further disposed on the bank 154. As illustrated in FIG. 6, the barrier RAS may be disposed at all the boundaries between the sub-pixels PX1, PX2, and PX3 (in the non-display area NEA (NEA1, NEA2, and NEA3)), but the embodiments of the present specification are not limited thereto. The barrier RAS may be disposed directly on an upper surface of the bank 154, but the embodiments of the present specification are not limited thereto. The barrier RAS may serve to separate the organic layer 152 from the boundaries of adjacent sub-pixels PX1, PX2, and PX3. In some embodiments, the barrier may be omitted, and a trench may be formed in the bank 154. The trench may recess the bank 154 in the thickness direction.

A spacer 155 may be further disposed on the bank 154. The spacer 155 may be formed of the same material as the bank 154, but the embodiments of the present specification are not limited thereto. For example, the spacer 155 may be a transparent bank, but is not limited thereto, and the spacer 155 may be formed of the same material as the bank 154. For example, the spacer 155 may be disposed on at least one of the boundaries of the first to third sub-pixels PX1, PX2, and PX3, but the embodiments of the present specification are not limited thereto. The bank 154 and the spacer 155 may be formed of the same material and formed simultaneously through a halftone mask, but the embodiments of the present specification are not limited thereto.

The organic layer 152 may be disposed on the first electrode 151, the bank 154, and the spacer 155. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present specification are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present specification are not limited thereto.

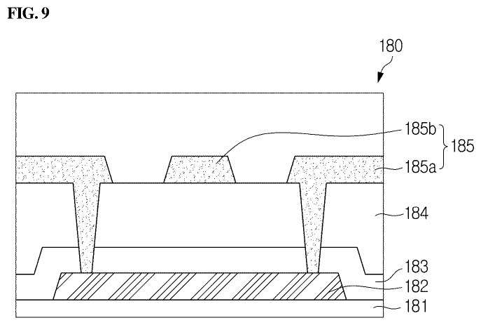

FIG. 9 is a cross-sectional view of a touch part according to FIG. 6 according to one embodiment.

Referring to FIGS. 6 and 9, the touch buffer layer 181 may be disposed on the encapsulation part 170. For example, a touch buffer layer 181 may be disposed on the third encapsulation layer 173. The touch buffer layer 181 may be formed of the same material as the buffer layer 102, but the embodiments of the present specification are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present specification are not limited thereto. The second touch insulating layer 184 may include an organic insulation material, but the embodiments of the present specification are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the sensor electrode 185 and the bridge electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

Referring back to FIG. 6, the filter insulating layer 114 may be disposed on the sensor electrode 185. The filter insulating layer 114 may be formed of an inorganic insulation material, such as silicon nitride (SiNₓ) or silicon oxide (SiOₓ), but the embodiments of the present specification are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3. The end of the bank 154 may be aligned with the boundaries between the light-emitting areas EA1, EA2, and EA3 and the non-light-emitting areas NEA1, NEA2, and NEA3, but the embodiments of the present specification are not limited thereto. In the case of the display panel 100 according to one embodiment, since the bank 154 may include a black-based material and the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3, light emitted from the light-emitting areas EA1, EA2, and EA3 may be emitted upward with a greater viewing angle as much as a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3 and the bank 154 is formed of only a transparent material, light incident from the outside may be reflected by the bank 154, resulting in visible ring-shaped spots. However, in the case of the display panel 100 according to one embodiment, the light incident from the outside may be absorbed or blocked by the bank 154 including a black-based material, thereby preventing the occurrence of the ring-shaped spots.

The color filters 191, 192, and 193 may be disposed on the black matrix BM. The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. A first color filter 191 may be provided to block light of other colors not including red (R) light. In this case, the first color filter 191 may be provided as a red color filter. A second color filter 192 may be provided to block light of other colors not including green (G) light. In this case, the second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the present specification are not limited thereto.

For example, each color filter 191, 192, or 193 may come into direct contact with side and upper surfaces of the black matrix BM. For example, each color filter 191, 192, or 193 may be spaced apart from the boundaries of adjacent sub-pixels PX1, PX2, and PX3, but the embodiments of the present specification are not limited thereto, and the color filters 191, 192, and 193 may overlap each other in the thickness direction.

The planarization layer OC may be disposed on the color filters 191, 192, and 193. The planarization layer OC may serve to planarize a step formed by the color filters 191, 192, and 193. For example, the planarization layer OC may include an organic insulation material.

Hereinafter, the transmissive area TA of the first optical area DA1 will be described. For contents that are substantially the same as those described in the pixel area PA among the descriptions of the transmissive area TA, the same reference numerals are given, and the overlapping contents may be omitted or briefly described.

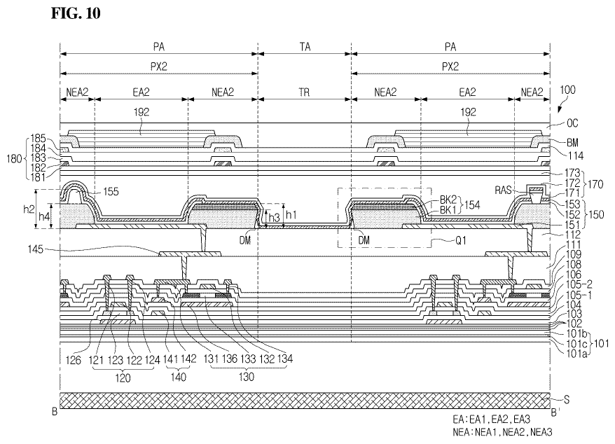

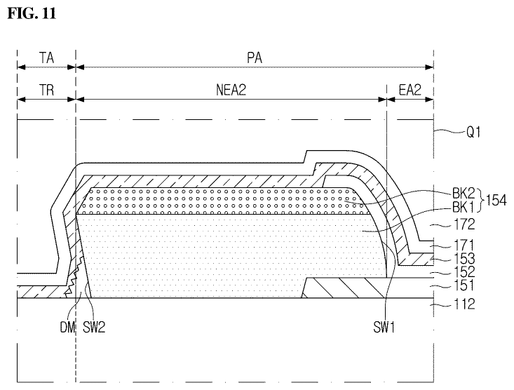

FIG. 10 is a cross-sectional view along line B-B′ in FIG. 5 according to one embodiment. FIG. 11 is an enlarged view of area Q1 in FIG. 10 according to one embodiment.

Referring to FIGS. 5, 6, 10, and 11, the first thin film transistor 120, the second thin film transistor 130, the storage capacitor 140, the light-emitting part 150, and the color filters 191, 192, and 193 may not be disposed in the transmissive area TA. Insulating layers disposed between the substrate 101 and the light-emitting part 150, the encapsulation part 170, the touch insulating layer, and the planarization layer OC may be disposed in the transmissive area TA.

The trench TR may be disposed in the transmissive area TA. The trench TR may be defined by the bank 154. The trench TR may be formed by recessing the bank 154 in the thickness direction. The trench TR may be formed so that the bank 154 is recessed to pass therethrough in the thickness direction. In this case, the trench TR may expose the second protective layer 112.

The first electrode 151 and the organic layer 152 of the light-emitting part 150 are not disposed in the transmissive area TA, and the second electrode 153 may be disposed.

The bank 154 may include a first bank layer BK1, and a second bank layer BK2 disposed on the first bank layer BK1, and the first bank layer BK1 and the second bank layer BK2 have different properties. The first bank layer BK1 may include a hydrophilic organic material, and the second bank layer BK2 may include a hydrophobic organic material.

For example, the first bank layer BK1 may be formed of an organic material, such as a polyimide resin, a hydrophilic acrylic resin, a photosensitive polymer, etc. However, the embodiments of the present specification are not limited thereto, and the first bank layer BK1 may further include a black-based material. For example, the first bank layer BK1 may be formed of a material containing black pigment, or an organic material, such as a benzocyclobutene resin, a polyimide resin, an acrylic resin, a photosensitive polymer, etc., but the embodiments of the present specification are not limited thereto. When the first bank layer BK1 is formed of a material containing black pigment, black dye, etc., the first bank layer BK1 may be an opaque bank. When the first bank layer BK1 is formed of a material containing black pigment or black dye, it is possible to shield external light or light reflected from the outside, thereby further increasing the luminance of the display apparatus.

For example, the second bank layer BK2 may be formed of polystyrene, polymethyl methacrylate (PMMA), benzocyclobutene series resin, a siloxane-based resin, a silane resin, a hydrophobic acrylic resin, etc. The second bank layer BK2 may further include a black-based material. For example, the second bank layer BK2 may further include a black pigment, etc.

The first bank layer BK1 may be disposed across the entire area of the non-light-emitting area NEA. The first bank layer BK1 may be disposed in the pixel area PA.

The second bank layer BK2 may be disposed adjacent to the trench TR around the trench TR. The second bank layer BK2 may be disposed on the first bank layer BK1 around the trench TR.

The second bank layer BK2 may be disposed on the first bank layer BK1, disposed in the non-light-emitting area NEA, and disposed along a boundary between the transmissive area TA and the pixel area PA.

A height h1 of an upper surface of the second bank layer BK2 may be lower than a height h2 of an upper surface of the spacer 155. Accordingly, even when the second bank layer BK2 is disposed on the first bank layer BK1, it is possible to suppress or prevent defects during FMM mask deposition. Here, the upper surface of the second bank layer BK2 may refer to a surface opposite to the encapsulation part 170.

A height h3 of the upper surface of the first bank layer BK1 in the area in which the second bank layer BK2 is disposed may be lower than a height h4 of the upper surface of the first bank layer BK1 in the area in which the second bank layer BK2 is not disposed, but the embodiments of the present specification are not limited thereto.

Here, each height h1, h2, h3, or h4 may refer to a height from the upper surface of the second protective layer 112. The upper surface of the second protective layer 112 may refer to a surface facing the first bank layer BK1.

The embodiments of the present specification are not limited thereto, but the first bank layers BK1 having different heights may be formed using a half-tone mask, a slit, etc. during the process of forming the first bank layer BK1.

The first bank layer BK1 may include a first sidewall SW1 defining the light-emitting area EA and a second sidewall SW2 defining the trench TR.

The first sidewall SW1 and the second sidewall SW2 of the first bank layer BK1 may be disposed between one surface and the other surface of the first bank layer BK1 to connect the one surface and the other surface of the first bank layer BK1. Here, the one surface of the first bank layer BK1 may refer to a surface facing the second protective layer 112, and the other surface of the first bank layer BK1 may refer to a surface opposite to the one surface. In this case, the second bank layer BK2 may be disposed on the other surface of the first bank layer BK1.

At least a part of the second bank layer BK2 may be exposed by the organic layer 152. A part of the second bank layer BK2, which is exposed by the organic layer 152, may come into direct contact with the second electrode 153.

The first sidewall SW1 of the first bank layer BK1 may be formed in a regularly-tapered shape, and the second sidewall SW2 may be formed in an inversely-tapered shape.

The organic layer 152 and the second electrode 153 may be sequentially disposed on the first sidewall SW1. The first sidewall SW1 may come into direct contact with the organic layer 152. Since the organic layer 152 may be disposed between the first sidewall SW1 and the second electrode 153, the first sidewall SW1 may not come into contact with the second electrode 153.

An organic residue DM and the second electrode 153 may be disposed on the second side wall SW2. The second sidewall SW2 may come into direct contact with the organic residue DM and the second electrode 153. The second sidewall SW2 may come into direct contact with the organic residue DM in some areas, and the organic residue DM may be disposed between the second sidewall SW2 and the second electrode 153. The second sidewall SW2 may come into direct contact with the second electrode 153 in the remaining areas.

The organic residue DM may include the same material as the organic layer 152 and further include a solvent material. For example, the solvent material may be at least one selected from 4-EGCol, DEGBE, TEGME, DEGEE, TPGME, TEG, EGHE, DPGPE, DEGBME, 1-PH-2-Pol, Carvacrol, 3-MBAol, TEGEE, TEGIPE, TTEGME, DEGHE, 3-M-3-MBol, 2,6-DM-3,5-HDone, etc.

The organic residue DM may be separated from the organic layer 152. The organic residue DM may be a residue remaining after the organic layer 152 is removed with the solvent material.

The organic residue DM may be disposed adjacent to the hydrophilic first bank layer BK1. The organic residue DM may be disposed adjacent to the second sidewall SW2 of the first bank layer BK1. The organic residue DM may be disposed between the first bank layer BK1 and the second protective layer 112.

The organic residue DM may overlap the first bank layer BK1 and the second bank layer BK2 in the thickness direction, but is not limited thereto.

At least a part of the organic residue DM may be disposed in the pixel area PA. Specifically, the entire area of the organic residue DM may be disposed in the pixel area PA, or a part thereof may be disposed in the pixel area PA, and the remaining area may protrude from the pixel area PA and may be disposed in the transmissive area TA.

As the organic layer 152 is removed from the transmissive area TA, the light transmittance of the transmissive area TA can be increased, and thus the optical electronic device S can receive external light more smoothly. Furthermore, since the optical electronic device S can be operated more smoothly, it is possible to suppress or prevent an operation defect of the display apparatus 1.

Hereinafter, a method of manufacturing a display apparatus of the present specification will be described. For contents that are substantially the same as those described with reference to FIGS. 1 to 11 among components included in the method of manufacturing a display apparatus, the same reference numerals are given, and the overlapping contents may be omitted or briefly described.

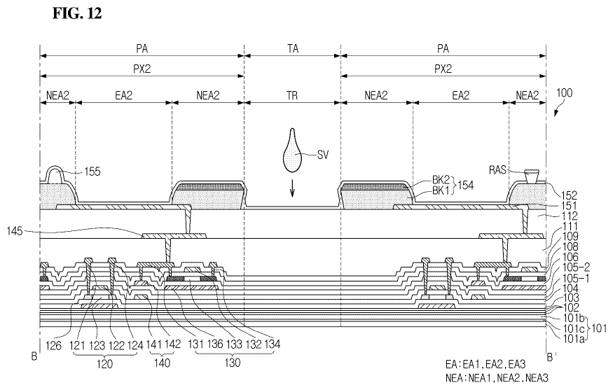

FIGS. 12 to 14 are views illustrating each process of a method of manufacturing a display apparatus according to one embodiment.

Referring to FIGS. 10 and 12, the first thin film transistor 120, the second thin film transistor 130, the storage capacitor 140, and the insulating layers disposed between the substrate 101 and the light-emitting part 150 are formed above substrate 101.

The first electrode 151 is patterned on the second protective layer 112, and the bank 154 is patterned on the first electrode 151. During the process of patterning the bank 154, the first bank layer BK1 and the second bank layer BK2 may be processed separately. After the first bank layer BK1 is patterned, the second bank layer BK2 is patterned.

During the process of patterning the first bank layer BK1, the first sidewall SW1 defining the light-emitting area EA may be patterned in a regularly-tapered shape, and the second sidewall SW2 defining the trench TR may be patterned in an inversely-tapered shape.

After the bank 154 is patterned, the organic layer 152 is coated. The organic layer 152 may be coated across the entire area of the substrate 101, but is not limited thereto. In this case, the organic layer 152 may be disposed on the bank 154 and disposed inside the trench TR and on the first electrode 151 exposed by the light-emitting area EA.

A solvent material SV may be coated on the organic layer 152 disposed in the trench TR. The solvent material SV may melt and remove the organic layer 152. The organic layer 152 may be removed from the transmissive area TA by the solvent material SV.

For example, the solvent material SV may be at least one selected from 4-EGCol, DEGBE, TEGME, DEGEE, TPGME, TEG, EGHE, DPGPE, DEGBME, 1-PH-2-Pol, Carvacrol, 3-MBAol, TEGEE, TEGIPE, TTEGME, DEGHE, 3-M-3-MBol, 2,6-DM-3,5-HDone, etc.

The second bank layer BK2 disposed around the trench TR may be formed of a hydrophobic material. Accordingly, it is possible to suppress or prevent the solvent material SV from overflowing to an adjacent other area (e.g., the light-emitting area EA) after removing the organic layer 152. Furthermore, it is possible to suppress or prevent a light-emitting defect of the sub-pixels PX1, PX2, and PX3.

In addition, even when the same FMM is used without changing the FMM forming each of the normal area NA (see FIG. 1) and the first optical area DA1, areas having different PPIs may be formed. Furthermore, it is possible to optimize the process of manufacturing a display apparatus, thereby reducing production energy.

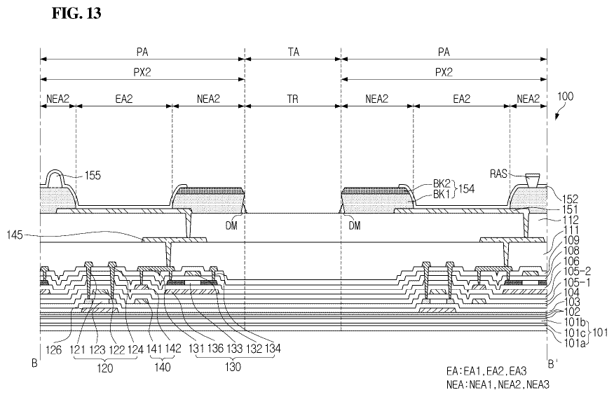

Subsequently, further referring to FIG. 13, the solvent material SV may be removed by vacuum drying (VCD), etc. Even when the solvent material SV is removed, the organic residue DM that remains after the organic layer 152 is removed may remain in the trench TR. The organic residue DM may be disposed adjacent to the hydrophilic second sidewall SW2 of the first bank layer BK1.

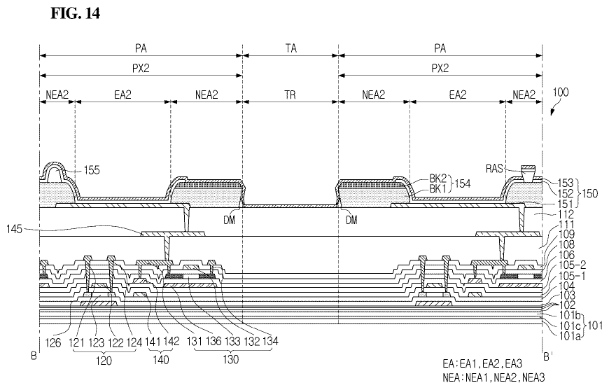

Subsequently, referring to FIG. 14, the second electrode 153 may be deposited on the organic layer 152. The second electrode 153 may be disposed across the entire area of the substrate 101. The second electrode 153 may be disposed on the organic layer 152 in the light-emitting area EA and disposed on the second protective layer 112 exposed by the trench TR in the trench TR. The second electrode 153 may cover the organic residue DM.

Although not illustrated, the encapsulation part 170, the touch part 180, the filter insulating layer 114, the black matrix BM, the color filters 191, 192, and 193, and the planarization layer OC may be sequentially disposed on the second electrode 153.

Hereinafter, other embodiments of the present specification will be described. For contents substantially the same as those described with reference to FIGS. 1 to 14 among components included in other embodiments, the same reference numerals are given, and the overlapping contents may be omitted or briefly described.

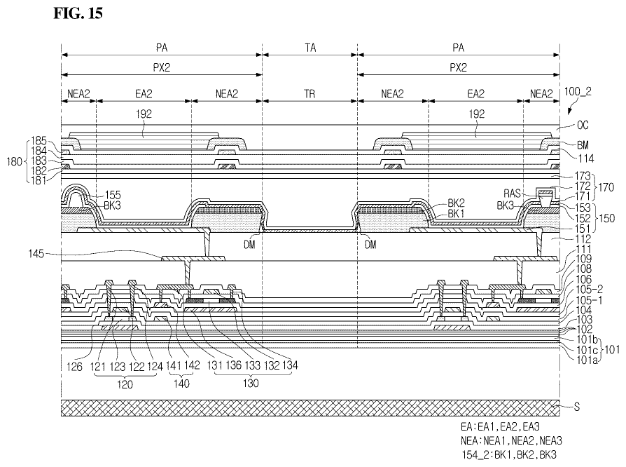

FIG. 15 is a cross-sectional view of a display apparatus according to another embodiment.

Referring to FIG. 15, a display panel 100_2 of the display apparatus according to the present embodiment includes a bank 154_2, and the bank 154_2 may further include a third bank layer BK3.

Specifically, the bank 154_2 may include the first bank layer BK1, the second bank layer BK2, and the third bank layer BK3. The third bank layer BK3 may be disposed on the first bank layer BK1. The third bank layer BK3 may be disposed on the first bank layer BK1 exposed by the second bank layer BK2.

The third bank layer BK3 may be disposed on the first bank layer BK1 in the area in which the second bank layer BK2 is not disposed. The first bank layer BK1 and the third bank layer BK3 may form side surfaces defining the light-emitting area EA, and the side surfaces defining the light-emitting area EA may have a regularly-tapered shape.

The third bank layer BK3 may include a hydrophilic organic material. The third bank layer BK3 may include the same material as the first bank layer BK1, but is not limited thereto.

In this case, the first bank layer BK1 may have a constant height across the entire area. Since a separate process for forming the first bank layers BK1 having different heights may not be necessary, the process can be more simplified.

Even in this case, the organic layer 152 may be omitted in the transmissive area TA, thereby increasing the light transmittance of the transmissive area TA. In addition, even when the same FMM is used without changing the FMM forming each of the normal area NA (see FIG. 1) and the first optical area DA1, areas having different PPIs may be formed. Furthermore, it is possible to optimize the process of manufacturing a display apparatus, thereby reducing production energy.

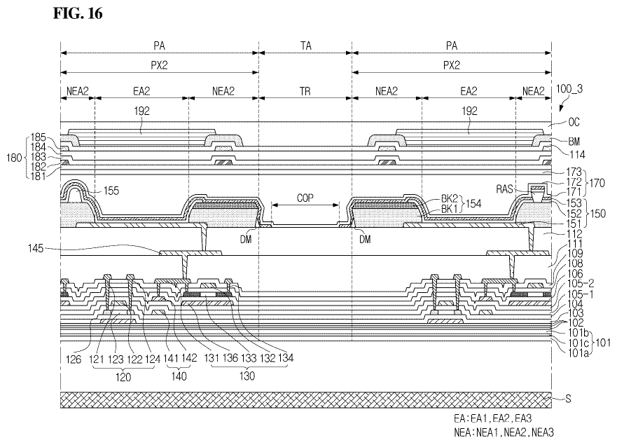

FIG. 16 is a cross-sectional view of a display apparatus according to still another embodiment.

Referring to FIG. 16, a display panel 100_3 of the display apparatus according to the present embodiment may further include the trench TR defined by the second electrode 153.

The second electrode 153 may be disposed in each trench TR, and an opening COP in which the second electrode 153 is recessed in the thickness direction in each trench TR may be defined.

The trench TR may be formed to pass through the bank in the thickness direction. In this case, the trench TR may expose the second protective layer 112 thereunder.

The opening COP may be disposed in each trench TR, and the entire area thereof may be disposed in each trench (TR), but the embodiments of the present specification are not limited thereto.

The first encapsulation layer 171 may come into direct contact with the second protective layer 112 in the opening COP, but is not limited thereto.

As least a part of the opening COP may be disposed in the transmissive area TA. Since the opening COP is disposed in the transmissive area TA, it is possible to increase the light transmittance of the transmissive area TA. Accordingly, the optical electronic device S can more smoothly receive external light of the display apparatus 1.

Even in this case, the organic layer 152 may be omitted in the transmissive area TA, thereby increasing the light transmittance of the transmissive area TA. In addition, even when the same FMM is used without changing the FMM forming each of the normal area NA (see FIG. 1) and the first optical area DA1, areas having different PPIs may be formed. Furthermore, it is possible to optimize the process of manufacturing a display apparatus, thereby reducing production energy.

A display apparatus according to various embodiments of the present specification may be described as follows.

According to embodiments of the present specification, there is provided a display apparatus including a substrate, a thin film transistor disposed on the substrate, a protective layer disposed on the thin film transistor, a first electrode disposed on the protective layer and electrically connected to the thin film transistor, a bank disposed across the first electrode and the protective layer and defining a light-emitting area exposing the first electrode and a trench exposing the protective layer, in which the bank defining the light-emitting area has a regularly-tapered shape, and the bank defining the trench has an inversely-tapered shape.

A display apparatus according to various embodiments of the present specification may further include an organic layer disposed in the light-emitting area, an organic residue disposed in the trench and separated from the organic layer, and a second electrode disposed on the organic layer and the organic residue.

According to various embodiments of the present specification, the organic residue may include the same material as the organic layer.

According to various embodiments of the present specification, the organic residue may further include a solvent material.

According to various embodiments of the present specification, the bank may include a first bank layer including a hydrophilic organic material, and a second bank layer disposed on the first bank layer and including a hydrophobic organic material.

According to various embodiments of the present specification, the first bank layer may include a first sidewall defining a light-emitting area and a second sidewall defining a trench, the first sidewall may have a regularly-tapered shape, and the second sidewall may have an inversely-tapered shape.

According to various embodiments of the present specification, the substrate may include a pixel area in which the light-emitting area is disposed and a transmissive area in which the trench is disposed, and the second bank layer may be disposed around the trench and disposed along a boundary between the pixel area and the transmissive area.

According to various embodiments of the present specification, a light transmittance of the transmissive area may be higher than a light transmittance of the pixel area.

According to various embodiments of the present specification, the bank may further include a spacer disposed on the bank, and a height of the second bank layer may be lower than a height of the spacer.

According to various embodiments of the present specification, the bank may further include a third bank layer including a hydrophilic organic material, and the third bank layer may be disposed on the first bank layer exposed by the second bank layer.

According to various embodiments of the present specification, the substrate may define a transmissive area and a pixel area that have different light transmittances, the thin film transistor, the first electrode, and the light-emitting area may be disposed in the pixel area, and the trench may be disposed in the transmissive area.

According to various embodiments of the present specification, each of the pixel area and the transmissive area may be provided as a plurality of areas, the plurality of pixel areas and the plurality of transmissive areas may have a zig-zag shape and extend in a first direction, and the pixel area and the transmissive area may be alternately and repeatedly disposed in a second direction intersecting the first direction.

According to various embodiments of the present specification, the substrate may further include a display area including a normal area and an optical area, and a non-display area disposed around the display area, the display area may include the normal area and the optical area having a lower PPI than the normal area, and the optical area may include a transmissive area and a pixel area.

The display apparatus according to various embodiments of the present specification may further include an optical electronic device disposed to overlap the optical area below the substrate.

The display apparatus according to various embodiments of the present specification may further include an organic layer disposed in a pixel area, and a second electrode disposed across a transmissive area and a pixel area, in which the organic layer may be disposed on a first electrode exposed by a bank, and the second electrode may be disposed on the organic layer and a protective layer exposed by the bank.

According to embodiments of the present specification, there is provided a display apparatus including a plurality of pixel areas in which a plurality of sub-pixels including a light-emitting area and a non-light-emitting area are disposed, a plurality of transmissive areas in which a trench is disposed, and a bank disposed between the plurality of pixel areas and defining the light-emitting area and the trench, in which the plurality of pixel areas and the plurality of transmissive areas extend in a first direction, the pixel areas and the transmissive areas are alternately and repeatedly disposed in a second direction intersecting the first direction, and the transmissive area has a higher light transmittance than the pixel area.

The display apparatus according to various embodiments of the present specification may further include a display area including a normal area and an optical area, and a non-display area disposed around the display area, in which the display area may include a normal area and an optical area having a lower PPI than the normal area, and the optical area may include a transmissive area and a pixel area.

According to various embodiments of the present specification, the optical electronic device may further be disposed to overlap the optical area.

According to various embodiments of the present specification, the bank defining the light-emitting area may have a regularly-tapered shape, and the bank defining the trench may have an inversely-tapered shape.

The display apparatus according to various embodiments of the present specification may further include an organic layer disposed in the light-emitting area, and an organic residue disposed in the trench and separated from the organic layer, in which the organic residue may include the same material as the organic layer, and a solvent material.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### Description of Reference Numerals

101: substrate
120: first thin film transistor
130: second thin film transistor
140: storage capacitor
150: light-emitting part
151: first electrode
152: organic layer
EML: light-emitting layer
153: second electrode
154: bank
BK: bank layer
170: encapsulation part
EA: light-emitting area
NEA: non-light-emitting area
TR: trench
TA: transmissive area
PA: pixel area
NA: normal area
DA1, DA2: optical area
COP: opening
S: optical electronic device

What is claimed is:

1. A display apparatus comprising:
a substrate;
a thin film transistor on the substrate;
a protective layer on the thin film transistor;
a first electrode on the protective layer, the first electrode electrically connected to the thin film transistor; and
a bank disposed across the first electrode and the protective layer and defining a light-emitting area exposing the first electrode and a trench exposing the protective layer,
wherein the bank defining the light-emitting area has a regularly-taped shape and the bank defining the trench has an inversely-tapered shape.

2. The display apparatus of claim 1, further comprising:
an organic layer in the light-emitting area;
an organic residue in the trench and separated from the organic layer; and
a second electrode on the organic layer and the organic residue.

3. The display apparatus of claim 2, wherein the organic residue includes a same material as the organic layer.

4. The display apparatus of claim 3, wherein the organic residue further includes a solvent material.

5. The display apparatus of claim 1, wherein the bank includes:
a first bank layer including a hydrophilic organic material; and
a second bank layer on the first bank layer, the second bank layer including a hydrophobic organic material.

6. The display apparatus of claim 5, wherein the first bank layer includes a first sidewall defining the light-emitting area and a second sidewall defining the trench, and
the first sidewall has a regularly-tapered shape and the second sidewall includes an inversely-tapered shape.

7. The display apparatus of claim 6, wherein the substrate includes a pixel area in which the light-emitting area is disposed and a transmissive area in which the trench is disposed, and the second bank layer is disposed around the trench and disposed along a boundary between the pixel area and the transmissive area.

8. The display apparatus of claim 7, wherein a light transmittance of the transmissive area is higher than a light transmittance of the pixel area.

9. The display apparatus of claim 5, further comprising:
a spacer on the bank,
wherein a height of the second bank layer is lower than a height of the spacer.

10. The display apparatus of claim 5, wherein the bank further includes a third bank layer including a hydrophilic organic material, and the third bank layer is on the first bank layer exposed by the second bank layer.

11. The display apparatus of claim 1, wherein the substrate defines a transmissive area and a pixel area that have different light transmittances, and
the thin film transistor, the first electrode, and the light-emitting area are in the pixel area and the trench is disposed in the transmissive area.

12. The display apparatus of claim 11, wherein each of the pixel area and the transmissive area are provided as a plurality of areas,
wherein a plurality of pixel areas and a plurality of transmissive areas have a zig-zag shape and extend in a first direction, and the pixel area and the transmissive area are alternately and repeatedly disposed in a second direction intersecting the first direction.

13. The display apparatus of claim 12, wherein the substrate further includes a display area including a normal area and an optical area, and a non-display area disposed around the display area,
the display area includes the normal area and the optical area having a lower pixels per inch (PPI) than the normal area, and the optical area includes the transmissive area and the pixel area.

14. The display apparatus of claim 13, further comprising:
an optical electronic device that overlaps the optical area below the substrate.

15. The display apparatus of claim 11, further comprising:
an organic layer in the pixel area; and
a second electrode disposed across the transmissive area and the pixel area,
wherein the organic layer is on the first electrode exposed by the bank and the second electrode is on the organic layer and the protective layer exposed by the bank.

16. A display apparatus comprising:
a plurality of pixel areas in which a plurality of sub-pixels including a display area and a non-display area are disposed;
a plurality of transmissive areas in which a trench is disposed; and
a bank between the plurality of pixel areas, the bank defining a light-emitting area and the trench,
wherein the plurality of pixel areas and the plurality of transmissive areas extend in a first direction,
wherein a pixel area from the plurality of pixel areas and a transmissive area from the plurality of transmissive areas are alternately and repeatedly disposed in a second direction intersecting the first direction, and
the transmissive area has a higher light transmittance than the pixel area.

17. The display apparatus of claim 16, further comprising:
a display area including a normal area and an optical area; and
a non-display area disposed around the display area,
the display area includes the normal area, and the optical area having a lower pixels per inch (PPI) than the normal area, and
the optical area includes the transmissive area and the pixel area.

18. The display apparatus of claim 17, further comprising:
an optical electronic device that overlaps the optical area.

19. The display apparatus of claim 16, wherein the bank defining the light-emitting area has a regularly-taped shape and the bank defining the trench has an inversely-tapered shape.

20. The display apparatus of claim 16, further comprising:
an organic layer in the light-emitting area;
an organic residue in the trench and separated from the organic layer,
wherein the organic residue includes a same material as the organic layer and a solvent material.
